(19) United States
(12) Patent Application Publication
(10) Pub. No.: US 2026/0247656 A1
(43) Pub. Date: Aug. 20, 2026

(54) SILICON CARBIDE POWER SEMICONDUCTOR DEVICE AND METHOD OF MANUFACTURING SAME

(71) Applicant: DB HiTek Co., Ltd., Bucheon-si (KR)

(72) Inventors: Seung Hyun KIM, Bucheon-si (KR); Hee Bae LEE, Bucheon-si (KR); Jae Yuhn MOON, Bucheon-si (KR); Sung Kyung JUNG, Bucheon-si (KR); Seok Young LEE, Bucheon-si (KR); Gyu Hyun JUNG, Bucheon-si (KR); Soon Jong PARK, Bucheon-si (KR)

(21) Appl. No.: 19/169,664

(22) Filed: Apr. 3, 2025

(30) Foreign Application Priority Data
Feb. 18, 2025 (KR) 10-2025-0020651

(51) Int. Cl. H10D 30/66; H10D 30/01; H10D 62/10; H10D 62/832; H10D 64/23

(52) U.S. Cl. CPC H10D 30/662; H10D 30/0291; H10D 62/127; H10D 64/2527; H10D 62/8325

(57) ABSTRACT

A silicon carbide power semiconductor device and a method of manufacturing the same seek to reduce electric field stress that can be applied to a gate insulation film under a gate electrode by forming a shield region in an expansion region of a JFET region between adjacent unit cell regions. A silicon carbide power semiconductor device may comprise: a substrate; a drift region disposed on the substrate; a pair of well regions spaced apart from each other on a surface of the drift region; a source region disposed within each well region of the pair of well regions; a gate insulation film disposed on the drift region; a gate electrode disposed on the gate insulation film; and a shield region disposed within a separation space between the pair of well regions within the drift region.

### CROSS REFERENCE TO RELATED APPLICATION

The present application claims priority to Korean Patent Application No. 10-2025-0020651, filed Feb. 18, 2025, the entire contents of which is incorporated herein for all purposes by this reference.

### BACKGROUND OF THE INVENTION

### Field of the Invention

The present disclosure relates to a silicon carbide power semiconductor device and a method of manufacturing the same and, more particularly, to a silicon carbide power semiconductor device and a method of manufacturing the same seeking to reduce electric field stress that can be applied to a gate insulation film under a gate electrode by forming a shield region in an expansion region of a JFET region between adjacent unit cell regions.

### Description of the Related Art

Silicon carbide (SiC) is a material that has a wide energy band gap, high insulation field, high electron saturation velocity, and high thermal conductivity compared to silicon. Due to these properties, SiC is attracting attention as a semiconductor material for high-temperature, high-voltage device applications.

Currently, for a silicon carbide power semiconductor device, a structure that increases the density of a cell area is being studied to lower the specific on resistance (Rsp) of the device.

FIG. 1 is a plan view showing a conventional silicon carbide power semiconductor device; FIG. 2a is a schematic aa′ cross-sectional view of the silicon carbide power semiconductor device according to FIG. 1; FIG. 2b is a schematic bb′ cross-sectional view of the silicon carbide power semiconductor device according to FIG. 1.

Referring to FIG. 1, when forming a silicon carbide power semiconductor device, for example, a cell region having a stripe-type planar shape may be transformed to apply a cell region C having an island-type planar shape. When applying the transformation in this way, even if the width size of a JFET region J between adjacent cell regions C is controlled by a first width size W1, there is bound to be an expansion region J1 in the JFET region J that has a second width size W2 that is larger than the first width size W1. Because of the expansion region J1, the spacing between well regions Pwell in a pair of adjacent cell regions C becomes relatively wider, and thus the area where a gate electrode G is exposed to the JFET region J also becomes wider.

Hereinafter, the side having a first width size W1 of the JFET region J is referred to as an un-expansion region J2.

Referring to FIGS. 2A and 2B, since the physical distance between a peak electric field E1 immediately below a first gate insulation film GO1 on the expansion region J1 and the first gate insulation film GO1 becomes relatively closer than the physical distance between a peak electric field E2 below a second gate insulation film GO2 on the un-expansion region J2 and the second gate insulation film GO2, the electric field that can be applied to the first gate insulation film GO1 may be relatively increased. As a result, the electric field stress that can be applied to the first gate insulation film GO1 increases, and therefore, high temperature reverse bias (HTRB) characteristics become weak, which may cause problems in the reliability of the device.

To solve the above-mentioned problems, the inventor of the present disclosure proposes a novel silicon carbide power semiconductor device with improved structure and a method of manufacturing the same.

### Documents of Related Art

(Patent Document 0001) Korean Patent No. 10-1896332 “SEMICONDUCTOR DEVICE AND METHOD OF MANUFACTURING SAME”

### SUMMARY OF THE INVENTION

The present disclosure has been made to solve the problems of the related art, and an objective of the present disclosure is to provide a silicon carbide power semiconductor device and a method of manufacturing the same seeking to reduce electric field stress that can be applied to a gate insulation film below a gate electrode by forming a shield region in an expansion region of a JFET region between adjacent unit cell regions, thereby preventing the reliability of the device from being deteriorated.

In addition, an objective of the present disclosure is to provide a silicon carbide power semiconductor device and a method of manufacturing the same seeking to increase channel density and improve on-resistance characteristics by arranging multiple cell areas in a grid or zigzag shape.

The present disclosure may be implemented by an embodiment having the following configuration to achieve the above-described objectives.

According to an embodiment of the present disclosure, there is provided a silicon carbide power semiconductor device, including: a substrate; a drift region on the substrate; a pair of well regions spaced apart from each other on a surface of the drift region; a source region within each individual well region of the pair of well regions; a gate insulation film on the drift region; a gate electrode on the gate insulation film; and a shield region within a separation space between the well regions within the drift region.

According to another embodiment of the present disclosure, in the silicon carbide power semiconductor device, the shield region and the pair of well regions may be first conductivity type impurity doped regions.

According to still another embodiment of the present disclosure, in the silicon carbide power semiconductor device, the shield region may be located on the surface of the drift region.

According to still another embodiment of the present disclosure, in the silicon carbide power semiconductor device, the shield region may be in contact with at least one of the well regions.

According to still another embodiment of the present disclosure, in the silicon carbide power semiconductor device, the shield region may be formed together with the well regions through a same process.

According to still another embodiment of the present disclosure, in the silicon carbide power semiconductor device, the shield region may connect the well regions.

According to still another embodiment of the present disclosure, the silicon carbide power semiconductor device may further include: a first ohmic contact within the individual well region; and a second ohmic contact on each source region.

According to still another embodiment of the present disclosure, a silicon carbide power semiconductor device may include: multiple cell regions arranged along rows and columns and spaced apart from each other; a JFET region between adjacent cell regions of the multiple cell regions; a shield region, which is a first conductivity type impurity doped region, on a side of the JFET region; a gate electrode covering the JFET region; and a gate insulation film having a planar shape corresponding to the gate electrode under the gate electrode.

According to still another embodiment of the present disclosure, in the silicon carbide power semiconductor device, each cell region of the multiple cell regions may include: a well region, which is a first conductivity type impurity doped region, on a surface side of a drift region; and a source region, which is a second conductivity type impurity doped region, within the well region, wherein the drift region may be located on a substrate.

According to still another embodiment of the present disclosure, in the silicon carbide power semiconductor device, the JFET region may include: an un-expansion region with a first width size; and an expansion region with a second width size, wherein the second width size may be larger than the first width size.

According to still another embodiment of the present disclosure, in the silicon carbide power semiconductor device, the shield region may be located within the expansion region.

According to still another embodiment of the present disclosure, in the silicon carbide power semiconductor device, the shield region may limit the second width size of the expansion region to an effective width size.

According to still another embodiment of the present disclosure, in the silicon carbide power semiconductor device, the multiple cell regions may be arranged in a grid pattern.

According to still another embodiment of the present disclosure, in the silicon carbide power semiconductor device, the multiple cell regions may be arranged in m rows and n columns, and a cell region among the multiple cell regions of column k (1<k<n) may be located in a different row from a nearest adjacent cell region of column k−1 and/or column k+1.

According to still another embodiment of the present disclosure, in the silicon carbide power semiconductor device, each cell region of the multiple cell regions may have a planar shape of island type.

According to still another embodiment of the present disclosure, in the silicon carbide power semiconductor device, the shield region may be connected to all well regions of cell regions among the multiple cell regions surrounding any single expansion region.

According to still another embodiment of the present disclosure, in the silicon carbide power semiconductor device, a plurality of shield regions may be arranged to be spaced apart within a single expansion region.

According to still another embodiment of the present disclosure, in the silicon carbide power semiconductor device, the shield region may connect well regions in some of a plurality of cell regions among the multiple cell regions surrounding any single expansion region.

According to an embodiment of the present disclosure, there is provided a method of manufacturing a silicon carbide power semiconductor device, the method including: forming a drift region on a substrate; forming a well region, which is a first conductivity type impurity doped region, and a shield region connected to the well region on a surface side of the drift region; forming a source region, which is a second conductivity type impurity doped region, within the well region; and forming a gate insulation film and a gate electrode on the drift region.

According to another embodiment of the present disclosure, in the method of manufacturing a silicon carbide power semiconductor device, the gate electrode may have an H-type planar shape.

The present disclosure has the following effects by the above configurations.

According to the present disclosure, by forming a shield region in an expansion region of a JFET region between adjacent unit cell regions, it is possible to reduce electric field stress that can be applied to a gate insulation film below a gate electrode, thereby preventing the reliability of the device from being deteriorated.

Furthermore, according to the present disclosure, by arranging multiple cell areas in a grid or zigzag shape, it is possible to increase channel density and improve on-resistance characteristics.

Meanwhile, it should be added that even if effects are not explicitly mentioned herein, the effects described in the following specification expected by the technical features of the present disclosure and their potential effects are treated as if they were described in the specification of the present disclosure.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a plan view showing a conventional silicon carbide power semiconductor device;

FIG. 2a is a schematic aa′ cross-sectional view of the silicon carbide power semiconductor device according to FIG. 1; FIG. 2b is a schematic bb′ cross-sectional view of the silicon carbide power semiconductor device according to FIG. 1;

FIG. 3 is a plan view showing a silicon carbide power semiconductor device according to a first embodiment of the present disclosure;

FIG. 4 is a plan view showing a silicon carbide power semiconductor device according to a second embodiment of the present disclosure;

FIG. 5 is a plan view showing the shape of a gate electrode in the silicon carbide power semiconductor device according to FIG. 3;

FIG. 6 is a cross-sectional view taken along line AA′ of the silicon carbide power semiconductor device according to FIG. 3;

FIG. 7 is a cross-sectional view taken along line BB′ of the silicon carbide power semiconductor device according to FIG. 3;

FIG. 8 is a cross-sectional view taken along line CC′ of the silicon carbide power semiconductor device according to FIG. 3;

FIGS. 9 to 13 are plan views showing the plane shape of a shield region according to the first embodiment of the present disclosure;

FIGS. 14 to 17 are plan views showing the plane shape of a shield region according to the second embodiment of the present disclosure;

FIGS. 18 to 25 are views showing a method of manufacturing a silicon carbide power semiconductor device according to an embodiment of the present disclosure.

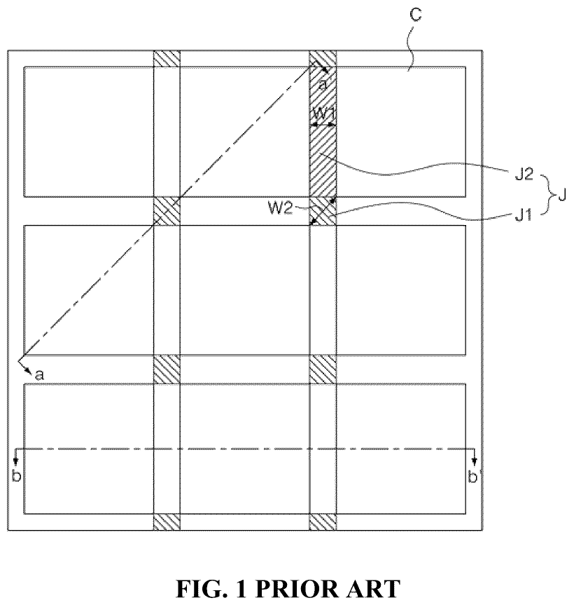

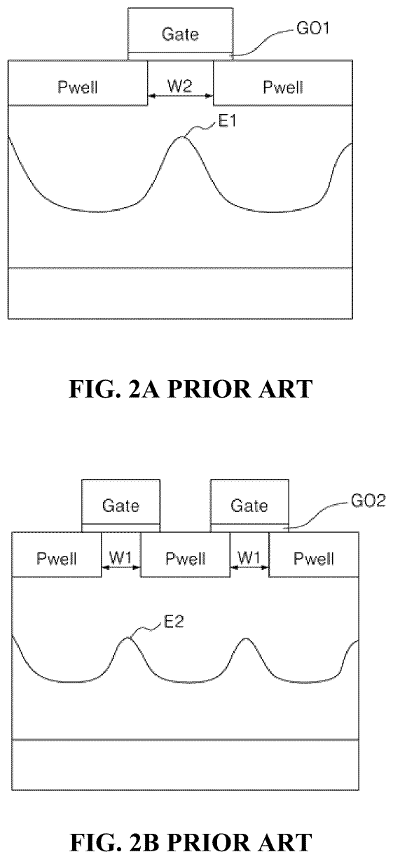

### DETAILED DESCRIPTION OF THE INVENTION

Hereinafter, embodiments of the present disclosure will be described in more detail with reference to the accompanying drawings. The embodiments of the present disclosure may be modified in various forms, and the scope of the present disclosure should not be construed as being limited to the following embodiments, but should be construed based on the matters described in the claims. In addition, these embodiments are only provided for reference in order to more completely explain the present disclosure to those of ordinary skill in the art.

As used herein, the singular form may include the plural form unless the context clearly indicates otherwise. In addition, as used herein, “comprise” and/or “comprising” specify the presence of the recited shapes, numbers, steps, operations, members, elements, and/or groups thereof, but do not exclude the presence or addition of one or more other shapes, numbers, steps, operations, members, elements, and/or groups thereof.

Hereinafter, it should be noted that when one component (or layer) is described as being disposed on another component (or layer), one component may be disposed directly on another component, or another component(s) or layer(s) may be located between the components. In addition, when one component is expressed as being directly disposed on or above another component, no other component(s) are located between the components. Moreover, being located on “top”, “upper”, “lower”, “top”, “bottom” or “one (first) side” or “side” of a component means a relative positional relationship.

Meanwhile, it should be noted that, where certain embodiments are otherwise feasible, certain process sequences may be performed other than those described below. For example, two processes described in succession may be performed substantially simultaneously or in the reverse order.

Hereinafter, a first conductivity type impurity region is understood as, for example, a “P-type” doped region, and a second conductivity type impurity region is understood as an “N-type” doped region. Alternatively, in some cases, the first conductivity type impurity region may be an “N-type” region and the second conductivity type impurity region may be a “P-type” doped region, but there is no limitation thereto.

In addition, in the following, the left-right direction (or x-axis direction) on the plan view is set as the “first direction”, and the up-down direction (or y-axis direction) on the plan view is set as the “second direction”.

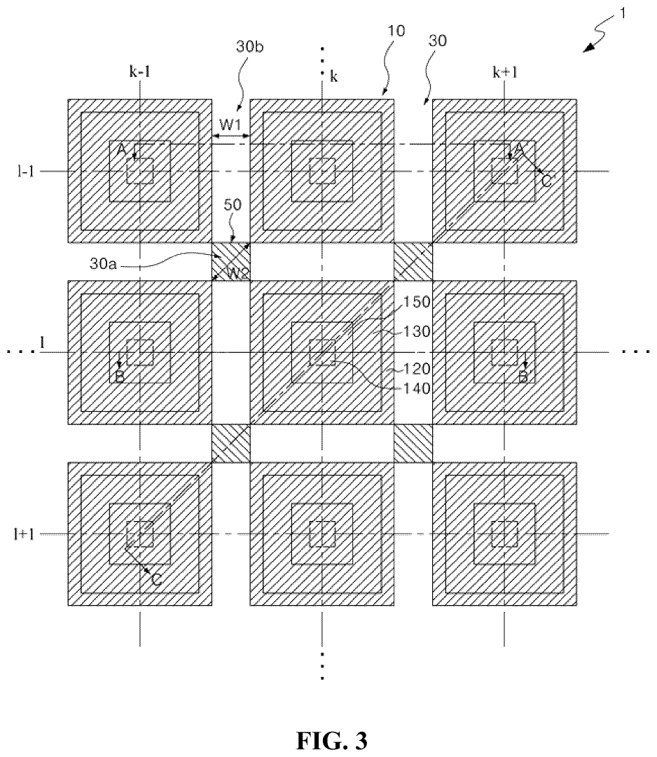

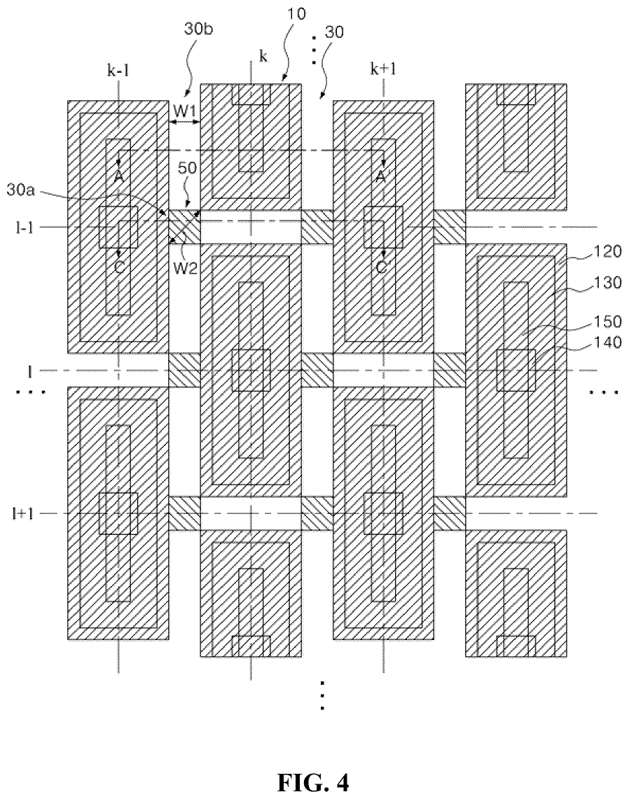

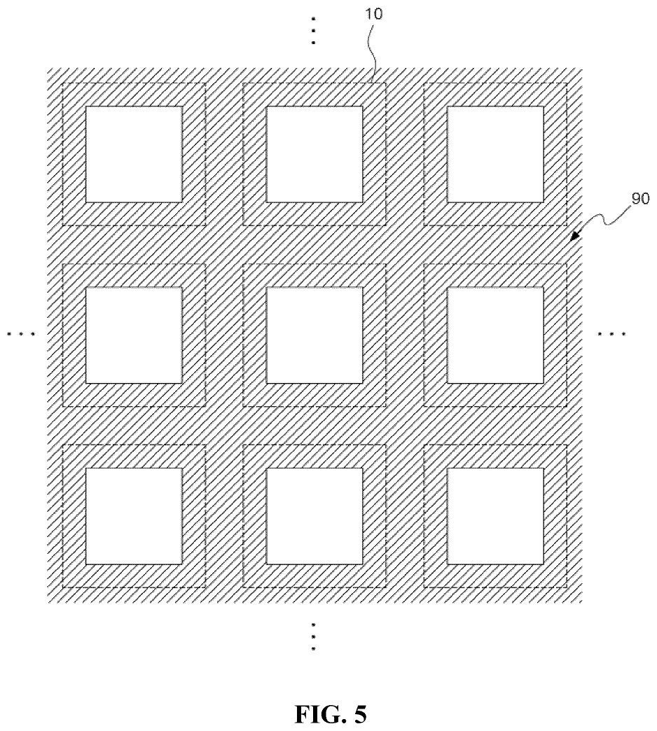

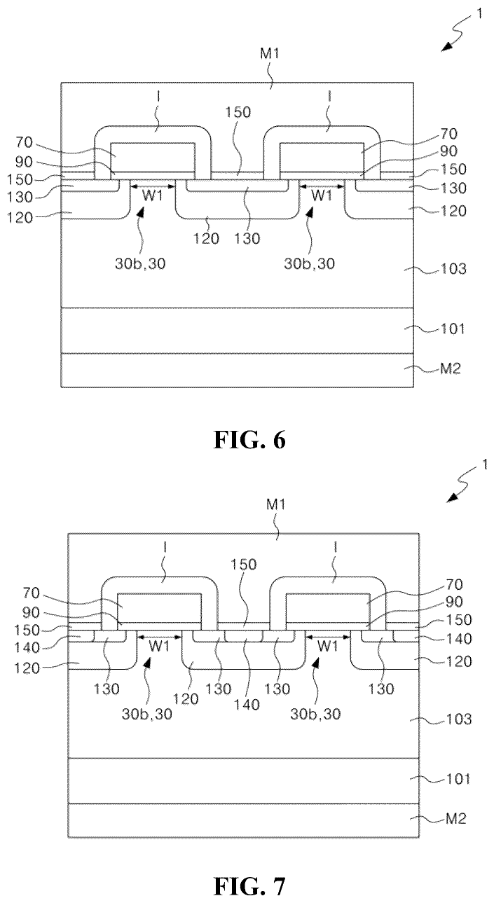

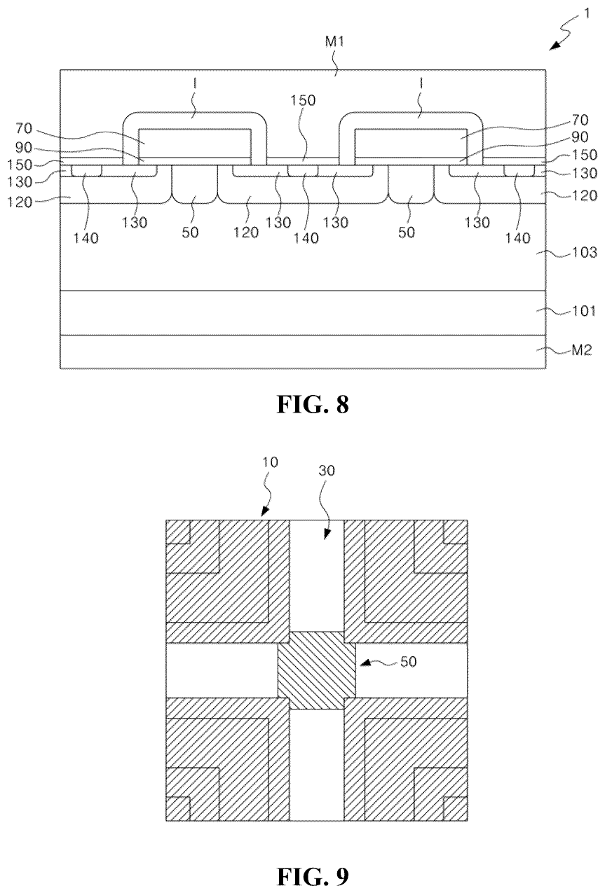

FIG. 3 is a plan view showing a silicon carbide power semiconductor device according to a first embodiment of the present disclosure; FIG. 4 is a plan view showing a silicon carbide power semiconductor device according to a second embodiment of the present disclosure; FIG. 5 is a plan view showing the shape of a gate electrode in the silicon carbide power semiconductor device according to FIG. 3; FIG. 6 is a cross-sectional view taken along line AA′ of the silicon carbide power semiconductor device according to FIG. 3; FIG. 7 is a cross-sectional view taken along line BB′ of the silicon carbide power semiconductor device according to FIG. 3; and FIG. 8 is a cross-sectional view taken along line CC′ of the silicon carbide power semiconductor device according to FIG. 3.

It should be noted that the upper structure of a drift region, such as a gate electrode, is omitted in FIGS. 3 and 4. In addition, the cross-sectional view of the silicon carbide power semiconductor device according to FIG. 4 is not separately illustrated, but is similar to the cross-sectional view of the silicon carbide power semiconductor device according to FIG. 3.

Hereinafter, a silicon carbide power semiconductor device 1 according to one embodiment of the present disclosure will be described in detail with reference to the attached drawings.

Referring to FIGS. 3 to 8, the present disclosure relates to the silicon carbide power semiconductor device 1 and, more particularly, to a silicon carbide power semiconductor device for reducing electric field stress that can be applied to a gate insulation film 90 below a gate electrode 70 by forming a shield region 50 in an expansion region 30a of a JFET region 30 between adjacent unit cell regions 10.

First, the cell region 10 may be formed in the silicon carbide power semiconductor device 1. The cell region 10 has a configuration in which the outer surface thereof in a plan view is determined by a well region 120 described later, and may have a planar shape of an island type. That is, the silicon carbide power semiconductor device 1 has a plurality of cell regions 10 arrayed, and the individual cell regions 10 may be spaced apart from each other, or at least some adjacent cell regions 10 may be spaced apart from each other. In addition, the individual cell region 10 may have a planar shape with the number of surface areas greater than or equal to a square. For example, the cell region 10 may have a planar shape of a square shape, a rectangular shape, or a hexagonal shape, but the scope of the present disclosure is not limited thereto.

Below, the array method of cell regions 10 is described in detail. Referring to FIG. 3, as a first example, when the cell regions 10 are arranged to have m rows and n columns (m and n are natural numbers), the cell regions 10 in each row and column may be arranged in a grid shape while being spaced apart from each other.

Referring to FIG. 4, as a second example, when the cell regions 10 are arranged to have m rows and n columns (m and n are natural numbers), any cell region of the kth column (1<k <n) may be arranged in a different row from that of the adjacent cell region of the k−1th column and/or the adjacent cell region of the k+1th column. To be specific, any cell region of the kth column may be arranged in the 1st row (1<l<m), and the adjacent cell region in the k−1th column and/or the adjacent cell region in the k+1th column may be arrayed in the l−1th row or the l+1th row. Accordingly, the cell regions 10 may be arranged in a zigzag shape along the first direction. In addition, the above “adjacent cell regions” are understood to mean the most adjacent cell regions along the first direction. In the second example, the individual cell region 10 may be formed in a square planar shape or a hexagonal planar shape, etc.

In the first and second examples, a JFET region 30 may be formed between adjacent cell regions 10.

Hereinafter, the silicon carbide power semiconductor device 1 according to one embodiment of the present disclosure will be described in detail.

Referring to FIGS. 3 to 8, first, the silicon carbide power semiconductor device 1 may be formed with a substrate 101. The substrate 101 may include, for example, a second conductivity type, high concentration impurity doped silicon carbide (SiC) wafer. To be specific, the substrate 101 may be, for example, a 4H-SiC or 6H-SiC substrate. This heavily doped substrate 101 may include, for example, phosphorus as a second conductivity type impurity.

In addition, a drift region 103 may be formed on the substrate 101. The drift region 103 may include, for example, a SiC epitaxial layer grown on the upper surface of the SiC single crystal substrate 101 while maintaining a specific orientation relationship with the crystal direction of the substrate 101. The drift region 103 may be formed by, for example, chemical vapor deposition (CVD), but is not limited thereto and may be formed by various processes such as molecular beam epitaxy (MBE), sublimation epitaxy, and liquid phase epitaxy.

In addition, the drift region 103 may be a region of lower concentration impurity doped region of the second conductivity type compared to the substrate 101, and may include, for example, phosphorus as the second conductivity type impurity. The substrate 101 and the drift region 103 above may be formed to cross both the cell region 10 and the JFET region 30.

The well region 120 may be formed on the surface side of the drift region 103 within the cell region 10. The well region 120 may be, for example, the first conductivity type impurity doped region, and a channel region, which is a current path, may be formed within the well region 120. A source region 130 may be formed on the surface side of the well region 120 within the well region 120. The source region 130 may be a highly doped region of the second conductivity type. For example, the source region 130 may be a region of the second conductivity type impurity doped with a higher impurity concentration compared to the drift region 103.

In addition, a first ohmic contact 140 may be further formed within the well region 120. The first ohmic contact 140 may be formed, for example, on the surface side of the well region 120 and positioned to be in contact with the source region 130. The first ohmic contact 140 is a first conductivity type impurity doped region, and may be a first conductivity type impurity doped region with a higher impurity concentration compared to the well region 120. It is preferable that the first ohmic contact 140 is formed only on one side of the individual cell region 10 along the second direction, and it is more preferable that the first ohmic contact 140 is formed only on the central side of the individual cell region 10. That is, the first ohmic contact 140 may have a short length along the second direction relative to the source region 130. In some cases, the first ohmic contact 140 may be omitted.

A second ohmic contact 150 for ohmic contact with a source metal M1 may be formed on the source region 130 within the cell region 10. This second ohmic contact 150 may include Ti or TiN, but the scope of the present disclosure is not limited thereto.

In addition, a drain metal M2 may be formed on the lower surface of the substrate 101. The drain metal M2 is configured to be electrically connected to a drain terminal (not shown), and may include, for example, Ni or Ag, but the scope of the present disclosure is not limited thereto. The drain metal M2 may be formed to cross the cell region 10 and the JFET region 30.

To further explain, as described above, the space between adjacent cell regions 10 may be the JFET (junction gate field-effect transistor) region.

Referring to FIGS. 3 and 4, generally, when the cell regions 10 are arranged in a stripe type in which the cell regions 10 are spaced apart from each other along the first direction and extends long along the second direction, unlike the first and second examples, the JFET region 30 between a pair of adjacent cell regions 10 has the first width size W1 that is substantially constant along the first direction.

However, when the cell regions 10 are formed in an island type to increase the channel density of the channel region as in the first and second examples, the expansion region 30a may be formed in which the width of the JFET region 30 is widened. For example, referring to FIG. 3, in the first example, the JFET region 30 between the cell region of row l−1 and column k−1, the cell region of row l and column k−1, the cell region of row l-1 and column k, and the four corners between the cell region of row l and column k is explained as follows, the JFET region 30 between the cell region of row l−1 and column k−1 and the cell region of row l−1 and column k has the first width size W1 that is substantially constant along the first direction. Thus, an un-expansion region 30b having the first width size W1 may be formed.

However, the JFET region 30 between the cell region of row l and column k−1 and the cell region of row l−1 and column k has a second width size W2 that is larger than the first width size W1 along the diagonal direction. That is, the expansion region 30a having the second width size W2 may be formed. As a result, the separation distance the well regions 120 respectively formed in the cell region 10 of row l and column k−1 and the cell region 10 of row l−1 and column k becomes relatively large, and accordingly, the area of the gate electrode 70 between the well regions 120 and the gate insulation film 90 under the gate electrode 70 exposed to the JFET region 30 becomes relatively large.

Consequently, the shielding effect of the gate insulation film 90 is reduced. That is, since the physical distance between a peak electric field E1 below the gate insulation film 90 on the expansion region 30a and the gate insulation film 90a becomes relatively closer than that of the un-expansion region 30b, and the electric field that can be applied to the gate insulation film 90 may be increased. As a result, the electric field stress that can be applied to the gate insulation film 90 increases, and therefore, there may be problems with the reliability of the device 1, such as high temperature reverse bias (HTRB) characteristics becoming weak.

Moreover, as in the first and second examples, because the area of the JFET region 30 itself increases when the cell regions 10 are formed in an island type to increase the channel density of the channel region, the structure of JFET region 30/gate insulation film 90/gate electrode 70 is formed relatively in large numbers, so that the gate leakage current increases, and the switching loss increases due to the increase in gate-drain capacitance (Cgd) and gate total charge (Qg).

In order to prevent the above problems, the silicon carbide power semiconductor device 1 according to an embodiment of the present disclosure is characterized by forming the shield region 50 in the expansion region 30a. The shield region 50 is a first conductivity type impurity doped region, and it is preferable that the shield region 50 has substantially the same doping concentration as the well region 120. “Having substantially the same doping concentration” is understood to mean that the well region 120 and the shield region 50 are formed through a single ion implantation process for implanting first conductivity type impurities.

FIGS. 9 to 13 are plan views showing the plane shape of a shield region according to the first embodiment of the present disclosure.

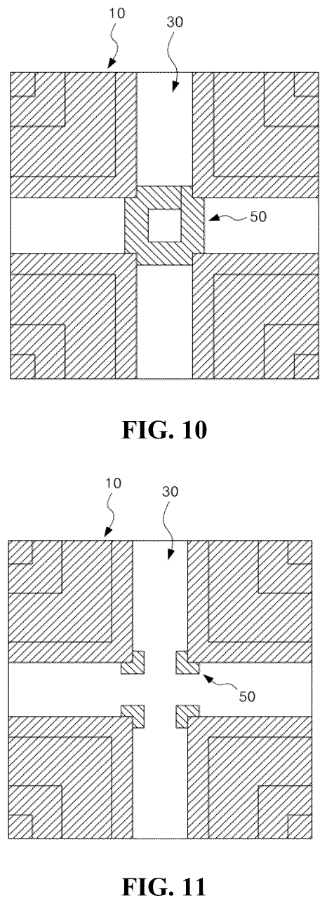

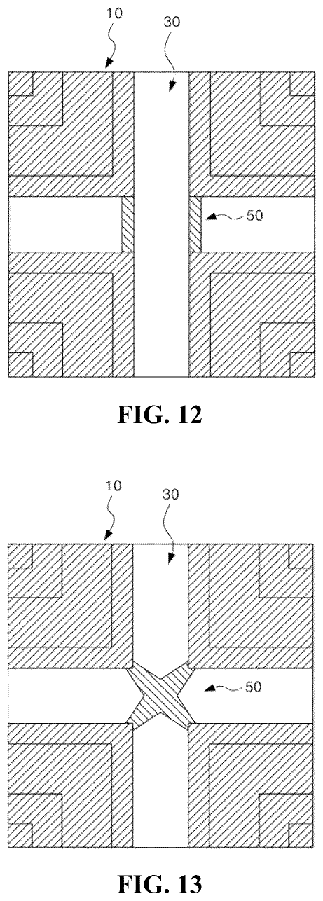

Referring to FIGS. 9 to 12, in the first example, the shield region 50 may have any suitable planar shape to form the effective width size of the expansion region 30a shorter than the second width size W2, wherein the expansion region 30a is between a pair of adjacent cell regions 10 (for example, a cell region in row l−1 and column k−1 and a cell region in row l and column k) in a diagonal direction. For example, the shield region 50 may have a variety of polygonal plane shapes, such as a square shape (see FIG. 9). Alternatively, the shield region 50 may have a planar shape with a polygonal border (see FIG. 10), a plurality of island-type planar shapes connected to adjacent well regions 120 (see FIG. 11), a stripe type planar shape (see FIG. 12), or any planar shape (see FIG. 13). The shield region 50 may have a cross-sectional shape extending from the well regions 120 and contacting the well regions 120 of at least some cell region(s) 10 among the adjacent multiple cell regions 10.

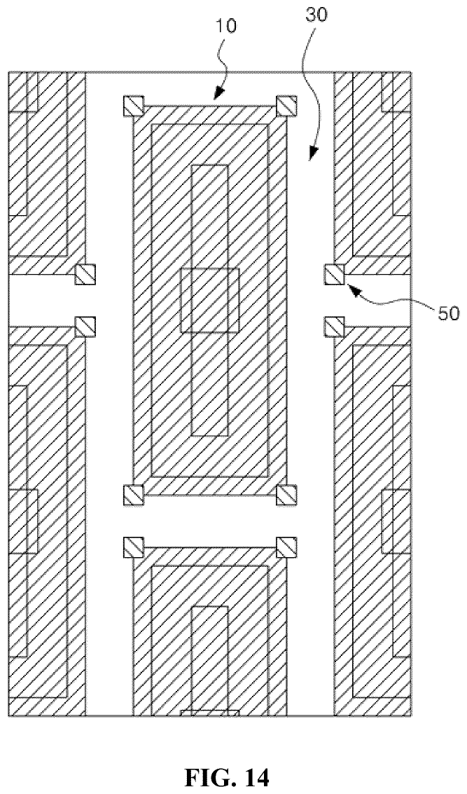

FIGS. 14 to 17 are plan views showing the plane shape of a shield region according to the second embodiment of the present disclosure.

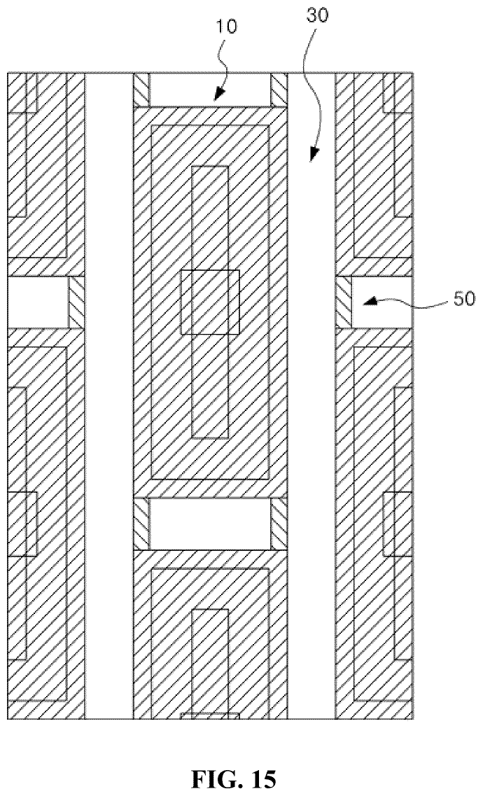

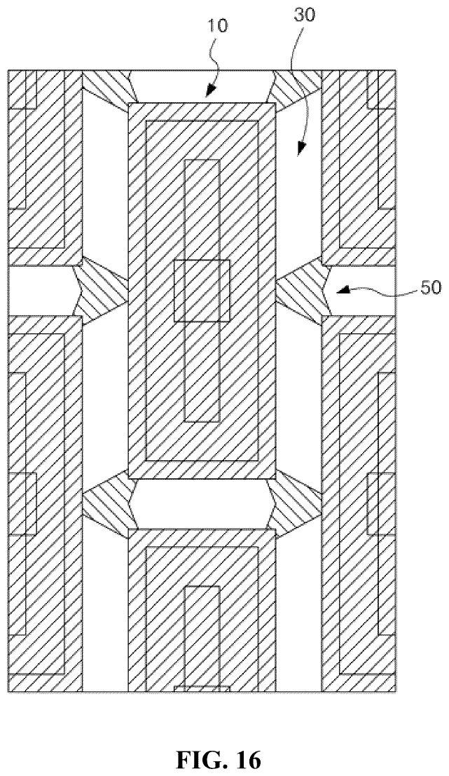

Referring to FIGS. 14 to 17, in the second example, the shield region 50 may have any suitable planar shape to form the effective width size of the expansion region 30a shorter than the second width size W2, wherein the expansion region 30a is between a pair of cell regions 10 arranged sequentially along the second direction in any k-th column (e.g., a pair of cell regions 10 arranged in the l-th row and the l+2-th row) and cell regions arranged in the l+1-th row in the k+1-th column. In the second example, the shield region 50 may have a plurality of island-type planar shapes connected to adjacent well regions 120 (see FIG. 14), a stripe type planar shape (see FIG. 15), or any planar shape (see FIGS. 16 and 17). The shield region 50 may have a cross-sectional shape extending from the well regions 120 and contacting the well regions 120 of at least some cell region(s) 10 among the adjacent multiple cell regions 10.

The above “effective width size” is understood to be the second width size W2 within a single expansion region 30a—the width size of the shield region 50 (or the sum of the width sizes of the shield regions 50).

To continue explanation with reference to FIGS. 3 to 8, the gate electrode 70 may be formed on the drift region 103. The gate electrode 70 may be formed on the drift region 103 so as to overlap with the well region 120 and the source region 130 in the vertical direction. In addition, the gate electrode 70 may be formed on the side covering the JFET region 30 on the drift region 103, but may be formed so as not to cover the second ohmic contact 150. Accordingly, the gate electrode 70 may have an H-type planar shape. The gate electrode 70 may include, for example, an impurity-doped polysilicon film.

Between the gate electrode 70 and the drift region 103, the gate insulation film 90 may be formed to have a planar shape corresponding to the gate electrode 70. The gate insulation film 90 may be, for example, an oxide film configuration.

An insulation film I may be formed to cover the gate electrode 70. The insulation film I may be formed to cover the sidewalls and the upper surface of the gate electrode 70. In addition, the source metal M1 may be formed on the drift region 103 to cover the insulation film I. The source metal M1 may be electrically connected to the source electrode (not shown).

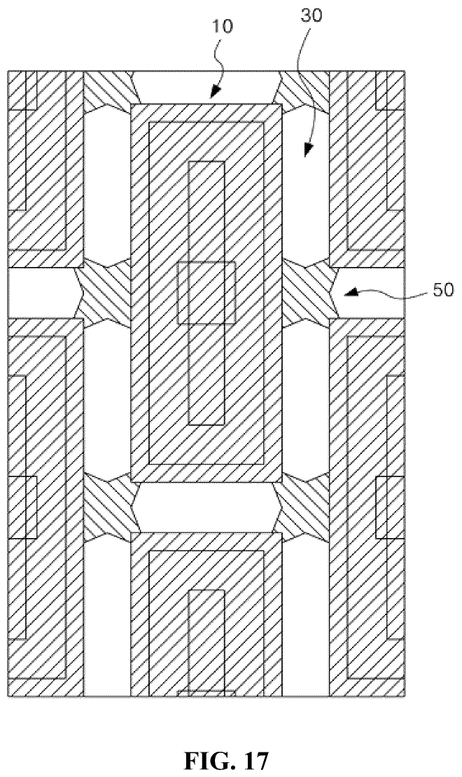

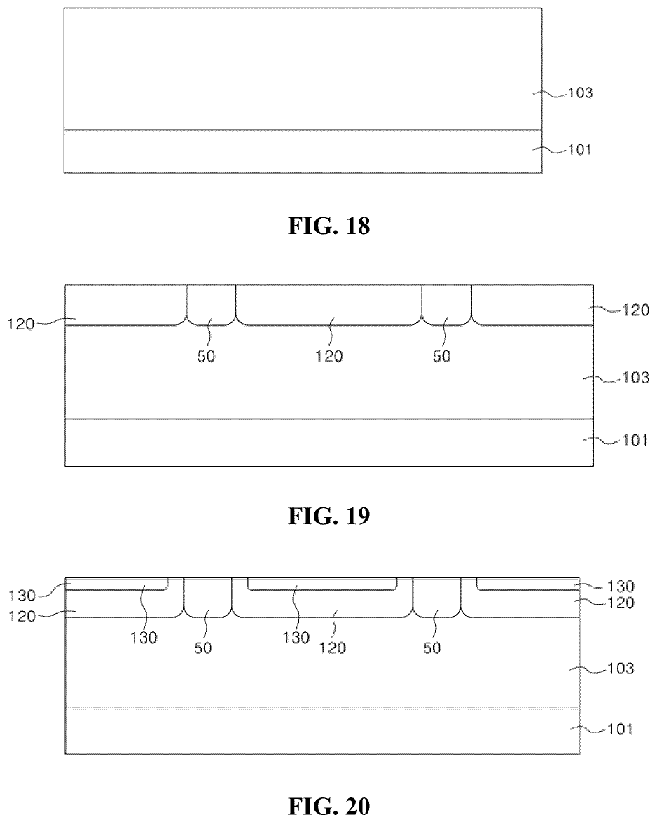

FIGS. 18 to 25 are views showing a method of manufacturing a silicon carbide power semiconductor device according to an embodiment of the present disclosure.

Hereinafter, a method of manufacturing a silicon carbide power semiconductor device according to one embodiment of the present disclosure will be described in detail. It should be noted that the above manufacturing method is not bound to the order described below.

Referring to FIG. 18, first, the drift region 103 is formed on the substrate 101. The drift region 103 is a layer formed, for example, through epitaxial growth on the substrate 101. The drift region 103 may be formed by chemical vapor deposition (CVD), but is not limited thereto and may be formed by various processes such as molecular beam epitaxy (MBE), sublimation epitaxy, and liquid phase epitaxy.

Afterwards, referring to FIG. 19, the well region 120 may be formed on the surface side of the drift region 103. At this time, the shield region 50 within the expansion region J1 may be formed together by utilizing a mask pattern (not shown). Both the well region 120 and the shield region 50 may be formed through an ion implantation process for implanting first conductivity type impurities. The shield region 50 may be physically connected to at least one well region 120 among the plurality of adjacent well regions 120. In contrast, if the shield region 50 is formed in an island type by being separated from all adjacent well regions 120, the profile of the mask pattern may become unstable, which limits the application thereof.

As a follow-up process, referring to FIG. 20, the source region 130 may be formed in the well region 120. The source region 130 may be formed through an ion implantation process for implanting second conductivity type impurities using a mask pattern (not shown). At this time, the source region 130 may correspond to a second conductivity type impurity doped region with a higher impurity concentration compared to the drift region 103.

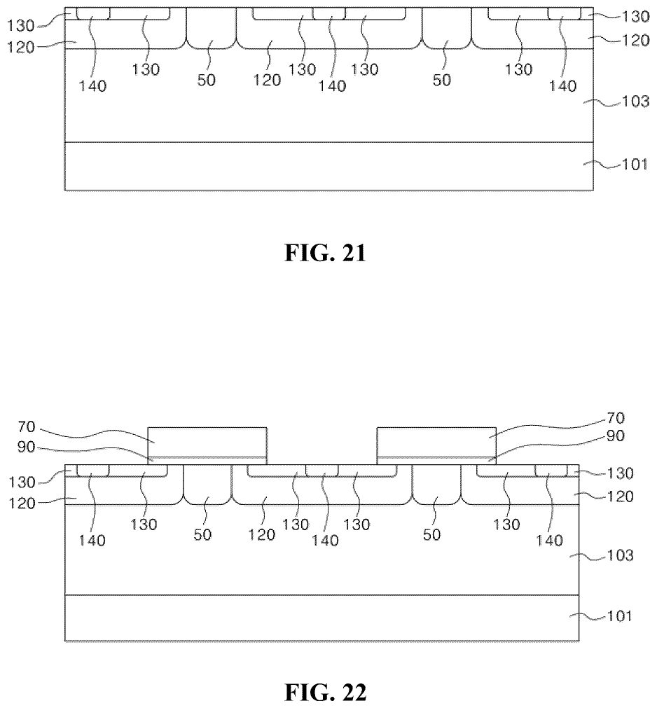

Afterwards, referring to FIG. 21, the first ohmic contact region 140 may be further formed within the well region 120. The first ohmic contact region 140 may be formed through an ion implantation process for implanting first conductivity type impurities using a mask pattern (not shown). It should be noted that in some cases, the source region 130 and the first ohmic contact region 140 may be formed through an ion implantation process after the gate electrode 70 is formed.

Then, referring to FIG. 22, the gate insulation film 90 and the gate electrode 70 may be formed on the drift region 103 and the JFET region 30) The gate insulation film 90 may be formed, for example, through an etching process after depositing an oxide film (not shown), and the gate electrode 70 may be formed through an etching process after depositing a polysilicon film (not shown).

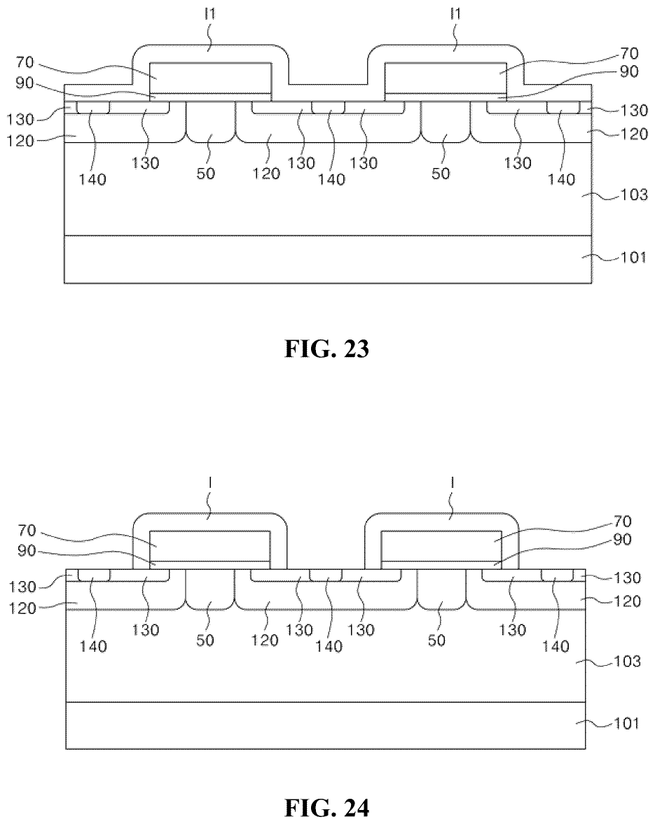

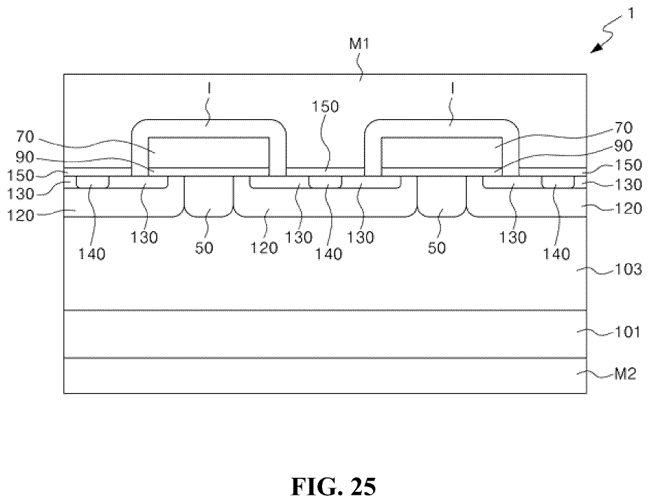

Afterwards, referring to FIG. 23, an insulation film layer I1 may be formed to cover the gate electrode 70 and the gate insulation film 90. Referring to FIG. 24 and FIG. 25, one side of the insulation film layer I1 may then be removed to form the second ohmic contact 150 on the side where the source region 130 is open. The second ohmic contact 150 may be formed through deposition and etching of a metal layer (not shown).

Finally, referring to FIG. 25, the source metal M1 and the drain metal M2 may be formed. The source metal M1 may be a metal layer such as Al, and the drain metal M2 may be a metal layer such as Ni or Ag. The source metal M1 may be formed to cover the ohmic contacts 140 and 150 and the gate electrode 70, and the drain metal M2 may be formed on the lower surface of the substrate 101.

The above detailed description is illustrative of the present disclosure. In addition, the above description shows and describes preferred embodiments of the present disclosure, and the present disclosure can be used in various other combinations, modifications, and environments. That is, changes or modifications are possible within the scope of the concept of the present disclosure disclosed herein, the scope equivalent to the written disclosure, and/or within the scope of skill or knowledge in the art. The above-described embodiment describes the best state for implementing the technical idea of the present disclosure, and various changes required in the specific application field and use of the present disclosure are possible. Accordingly, the detailed description of the present disclosure is not intended to limit the present disclosure to the disclosed embodiments.

What is claimed is:

1. A silicon carbide power semiconductor device, comprising:
a substrate;
a drift region disposed on the substrate;
a pair of well regions spaced apart from each other on a surface of the drift region;
a source region disposed within each well region of the pair of well regions;
a gate insulation film disposed on the drift region;
a gate electrode disposed on the gate insulation film; and
a shield region disposed within a separation space between the pair of well regions within the drift region.

2. The silicon carbide power semiconductor device of claim 1, wherein the shield region and the pair of well regions are first conductivity type impurity doped regions.

3. The silicon carbide power semiconductor device of claim 1, wherein the shield region is disposed on the surface of the drift region.

4. The silicon carbide power semiconductor device of claim 1, wherein the shield region is in contact with at least one of the pair of well regions.

5. The silicon carbide power semiconductor device of claim 1, wherein the shield region is formed together with the pair of well regions through a same process.

6. The silicon carbide power semiconductor device of claim 1, wherein the shield region connects the pair of well regions.

7. The silicon carbide power semiconductor device of claim 2, further comprising:
a first ohmic contact disposed within each well region of the pair of well regions; and
a second ohmic contact disposed on the source region disposed within each well region of the pair of well regions.

8. A silicon carbide power semiconductor device, comprising:
multiple cell regions arranged along rows and columns and spaced apart from each other;
a JFET region disposed between adjacent cell regions of the multiple cell regions;
a shield region, which is a first conductivity type impurity doped region, disposed on a side of the JFET region;
a gate electrode covering the JFET region; and
a gate insulation film having a planar shape corresponding to the gate electrode under the gate electrode.

9. The silicon carbide power semiconductor device of claim 8,
wherein each cell region of the multiple cell regions comprises:
a well region, which is another first conductivity type impurity doped region, disposed on a surface side of a drift region; and
a source region, which is a second conductivity type impurity doped region, disposed within the well region,
wherein the drift region is disposed on a substrate.

10. The silicon carbide power semiconductor device of claim 9,
wherein the JFET region comprises:
at least one un-expansion region having a first width size; and
at least one expansion region having a second width size,
wherein the second width size is larger than the first width size.

11. The silicon carbide power semiconductor device of claim 10, wherein the shield region is disposed within each of the at least one expansion region.

12. The silicon carbide power semiconductor device of claim 10, wherein the shield region limits the second width size of the at least one expansion region to an effective width size.

13. The silicon carbide power semiconductor device of claim 8, wherein the multiple cell regions are arranged in a grid pattern.

14. The silicon carbide power semiconductor device of claim 8,
wherein the multiple cell regions are arranged in m rows and n columns, the m denoting a predetermined number of rows and the n denoting a predetermined number of columns, and
wherein a cell region among the multiple cell regions of column k (1<k<n) is disposed in a different row from a nearest adjacent cell region of column k−1 and/or column k+1.

15. The silicon carbide power semiconductor device of claim 8, wherein each cell region of the multiple cell regions has a planar shape of an island type.

16. The silicon carbide power semiconductor device of claim 10, wherein the shield region is connected to all well regions of some cell regions among the multiple cell regions, the some cell regions surrounding a single expansion region of the at least one expansion region.

17. The silicon carbide power semiconductor device of claim 10, wherein a plurality of shield regions is arranged to be spaced apart within a single expansion region.

18. The silicon carbide power semiconductor device of claim 10, wherein the shield region connects well regions in some of a plurality of cell regions among the multiple cell regions, the plurality of cell regions surrounding a single expansion region of the at least one expansion region.

19. A method of manufacturing a silicon carbide power semiconductor device, the method comprising:
forming a drift region on a substrate;
forming a well region, which is a first conductivity type impurity doped region, and a shield region connected to the well region on a surface side of the drift region;
forming a source region, which is a second conductivity type impurity doped region, within the well region; and
forming a gate insulation film and a gate electrode on the drift region.

20. The method of claim 19, wherein the gate electrode has an H-type planar shape.
